(19) United States
(12) Patent Application Publication
(10) Pub. No.: US 2021/0126103 A1
(43) Pub. Date: Apr. 29, 2021

(54) APPARATUS COMPRISING WORDLINES COMPRISING MULTIPLE METAL MATERIALS, AND RELATED METHODS AND ELECTRONIC SYSTEMS

(71) Applicant: Micron Technology, Inc., Boise, ID (US)

(72) Inventor: Hidekazu Nobuto, Higashihiroshima (JP)

(21) Appl. No.: 16/667,654

(22) Filed: Oct. 29, 2019

(51) Int. Cl. H01L 29/49; H01L 27/108; H01L 29/423; H01L 23/532; H01L 29/40; H01L 21/28; H01L 21/285

(52) U.S. Cl. CPC H01L 29/4966; H01L 27/10823; H01L 29/4236; H01L 21/28568; H01L 29/401; H01L 21/28088; H01L 23/53266

(57) ABSTRACT

An apparatus comprising a wordline in a material, the wordline comprising a first metal portion, a second metal portion vertically adjacent to the first metal portion, and a third metal portion vertically adjacent to the second metal portion. A dielectric material is between the wordline and the material. Additional apparatus are disclosed, as are related methods of forming an apparatus and electronic systems.

### TECHNICAL FIELD

Embodiments disclosed herein relate to apparatus and apparatus fabrication. More particularly, embodiments of the disclosure relate to multiple metal material wordlines of apparatus and to related methods and electronic systems.

### BACKGROUND

Electronic device (e.g., apparatus, semiconductor device, memory device) designers often desire to increase the level of integration or density of features (e.g., components) within an electronic device by reducing the dimensions of the individual features and by reducing the separation distance between neighboring features. Electronic device designers also desire to design architectures that are not only compact, but offer performance advantages, as well as simplified designs. Reducing the dimensions and spacing of features has placed increasing demands on the methods used to form the electronic devices. A relatively common electronic device is a memory device. A memory device may include a memory array having a number of memory cells arranged in a grid pattern. One type of memory cell is a dynamic random access memory (DRAM) device, which is a volatile memory device that may lose a stored state over time unless the DRAM device is periodically refreshed by an external power supply. In the simplest design configuration, a DRAM cell includes one access device (e.g., a transistor) and one storage device (e.g., a capacitor). Modern applications for memory devices may utilize vast numbers of DRAM unit cells, arranged in an array of rows and columns. The DRAM cells are electrically accessible through digit lines (e.g., bit lines) and access lines (e.g., wordlines) arranged along the rows and columns of the array.

In conventional wordline structures, the wordline includes a single material (i.e., titanium nitride (TiN)) or a hybrid wordline of titanium nitride and tungsten (TiN/W). In the hybrid wordline, titanium nitride is formed on sidewalls of a trench and a tungsten core is formed in the trench and between the titanium nitride on opposing sidewalls. However, the titanium nitride wordline has a relatively high resistivity and, therefore, is not effective as a wordline material. In the TiN/W hybrid wordline, the titanium nitride is necessary as a barrier and adhesion material for the tungsten core. Since tungsten has a lower resistivity than titanium nitride, the TiN/W hybrid wordline has a lower wordline resistance than the titanium nitride wordline. However, forming the titanium nitride as a thin layer on sidewalls of a dielectric material is difficult. In addition, as the amount of tungsten in the TiN/W hybrid wordline decreases relative to the amount of titanium nitride, the resistivity of the TiN/W hybrid wordline increases. The relative amount of the nucleation tungsten to bulk tungsten also affects the resistivity of the TiN/W hybrid wordline, with the nucleation tungsten exhibiting a higher resistivity than the bulk tungsten. The wordline structures are also prone to bending.

With the decrease in dimensions and spacing, trenches in which the wordlines are formed are becoming smaller (e.g., narrower). However, forming the titanium nitride wordline or the TiN/W hybrid wordline in the smaller trenches is difficult and wordlines including thinner tungsten materials have a higher wordline resistance than wordlines including thicker tungsten materials. Furthermore, as the TiN/W hybrid wordlines occupies a large volume of the trenches, the wordline resistance increases. The tungsten of the TiN/W hybrid wordlines is formed by an ALD process that uses a fluorine-based tungsten precursor, such as WF₆, and hydrogen gas. However, using WF₆ as the tungsten precursor produces HF, which etches the tungsten and results in poor formation.

### BRIEF DESCRIPTION OF THE DRAWINGS

FIG. 1 is a cross-sectional view of a wordline structure including a wordline according to embodiments of the disclosure;

FIG. 2 is a cross-sectional view of a wordline structure including a wordline according to embodiments of the disclosure;

FIGS. 3-5 are cross-sectional views of various stages of forming the wordline structure of FIG. 1;

FIGS. 6-8 are cross-sectional views of various stages of forming the wordline structure of FIG. 2;

FIG. 9 is a schematic block diagram illustrating an electronic device that includes wordlines and wordline structures according to embodiments of the disclosure;

FIG. 10 is a top plan view of an array that includes the wordlines and wordline structures according to embodiments of the disclosure, where the view of FIG. 10 is taken along section line A-A of FIG. 9;

FIG. 11 is a schematic block diagram illustrating a system including the wordlines and wordline structures according to embodiments of the disclosure;

FIGS. 12A and 12B are scanning electron microscopy (SEM) micrographs of wordlines according to embodiments of the disclosure; and

FIGS. 13A and 13B are SEM micrographs of wordlines according to embodiments of the disclosure.

### DETAILED DESCRIPTION

An electronic device (e.g., an apparatus, a semiconductor device, a memory device) that includes an access line (e.g., a wordline) containing multiple metal-containing materials is disclosed. The wordline according to embodiments of the disclosure exhibits a reduced wordline resistance compared to conventional wordlines containing titanium nitride or a hybrid structure of titanium nitride and tungsten. The metal-containing materials of the wordline are in a vertical orientation relative to one another. The wordline includes a lower metal-containing material, a middle metal-containing material, and an upper metal-containing material. The middle metal-containing material may exhibit a lower resistivity than the resistivity of the lower and upper metal-containing materials. The lower metal-containing material may include a single metal material or two metal materials. The lower metal-containing material may be substantially homogeneous in chemical composition or may be heterogeneous in chemical composition. The metal-containing materials include metal atoms or metal atoms and nitrogen atoms. Thus, the metal-containing materials comprise, consist essentially of, or consist of the metal.

The wordline is formed by a so-called “bottom up process” that enables the wordline to be formed without a barrier material or an adhesion material present on sidewalls of a dielectric material of a wordline structure including the wordline. The bottom up process also eliminates forming a nucleation portion of the middle metal-containing material. The wordline is, thus, in direct contact with the dielectric material. An electronic device including the wordline according to embodiments of the disclosure exhibits minimal line bending and a decreased wordline resistance compared to electronic devices including conventional titanium nitride or titanium nitride and tungsten wordlines. The electronic device exhibits these properties with minimal degradation (e.g., deterioration) of access device (e.g., transistor) performance in the electronic device.

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of an electronic device or a complete process flow for manufacturing the electronic device and the structures described below do not form a complete electronic device. Only those process acts and structures necessary to understand the embodiments described herein are described in detail below. Additional acts to form a complete electronic device may be performed by conventional techniques.

Unless otherwise indicated, the materials described herein may be formed by conventional techniques including, but not limited to, spin coating, blanket coating, chemical vapor deposition (“CVD”), atomic layer deposition (“ALD”), plasma enhanced ALD, physical vapor deposition (“PVD”) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

Drawings presented herein are for illustrative purposes only, and are not meant to be actual views of any particular material, component, structure, device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an,” and “the” are intended to include the plural forms as well, unless the context clearly indicates otherwise.

As used herein, “and/or” includes any and all combinations of one or more of the associated listed items.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “configured” refers to a size, shape, material composition, and arrangement of one or more of at least one structure and at least one apparatus facilitating operation of one or more of the structure and the apparatus in a pre-determined way.

As used herein, the term “electronic device” includes, without limitation, a memory device, as well as semiconductor devices which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may be a 3D electronic device including, but not limited to, a 3D DRAM memory device or a 3D NAND Flash memory device, such as a 3D floating gate NAND Flash memory device or a 3D replacement gate NAND Flash memory device.

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, no intervening elements are present.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “substrate” means and includes a material (e.g., a base material) or construction upon which additional materials are formed. The substrate may be a an electronic substrate, a semiconductor substrate, a base semiconductor layer on a supporting structure, an electrode, an electronic substrate having one or more materials, layers, structures, or regions formed thereon, or a semiconductor substrate having one or more materials, layers, structures, or regions formed thereon. The materials on the electronic substrate or semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOT”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

As used herein, the term “wordline” means and includes a conductive structure including three metal-containing materials positioned in a vertical orientation relative to one another.

As used herein, the term “wordline structure” means and includes a component of an electronic device that includes the wordline.

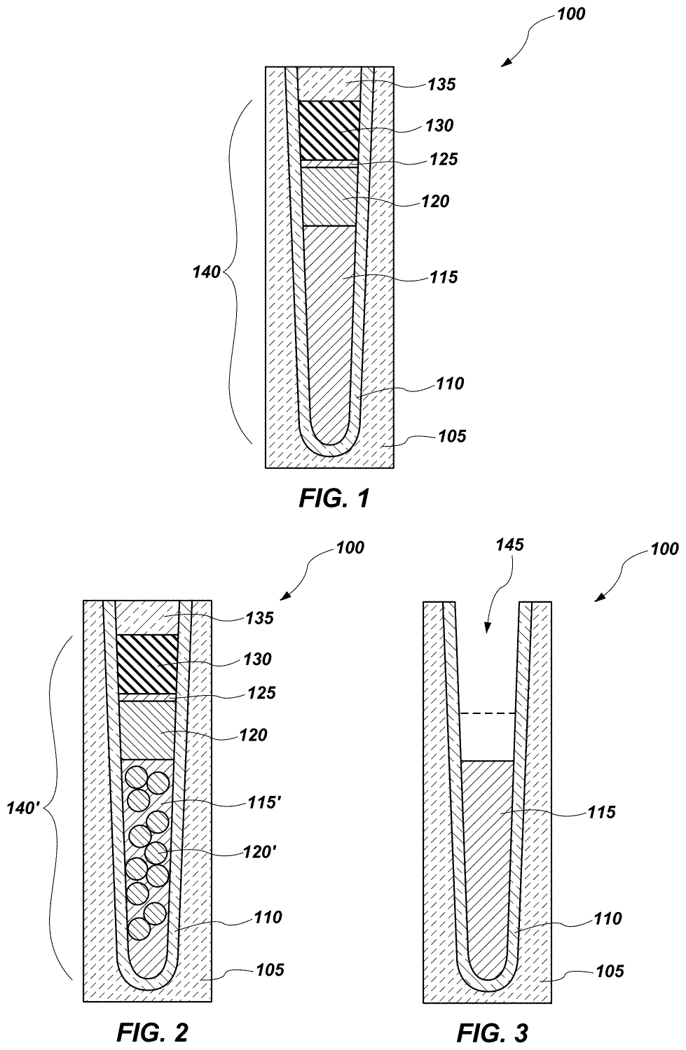

As shown in FIG. 1, a wordline structure 100 includes a substrate 105, a dielectric material 110, a first titanium nitride material 115, a metal material 120, and a second titanium nitride material 125. The first titanium nitride material 115 may be the lower metal-containing material, the metal material 120 may be the middle metal-containing material, and the second titanium nitride material 125 may be the upper metal-containing material. The first titanium nitride material 115 is present in a lower portion of the wordline structure 100, the metal material 120 is adjacent to (e.g., over) the first titanium nitride material 115, and the second titanium nitride material 125 is adjacent to (e.g., over) the metal material 120. The first titanium nitride material 115 may be substantially homogeneous in chemical composition. The metal material 120 may exhibit a lower resistivity than the first and second titanium nitride material 115, 125. The metal material 120 is present in a middle portion of the wordline structure 100. The first titanium nitride material 115, the metal material 120, and the second titanium nitride material 125 form the access line (e.g., wordline 140). The metal material 120 is in direct contact with (e.g., directly vertically adjacent to) the first titanium nitride material 115 and the second titanium nitride material 125 is in direct contact with (e.g., directly vertically adjacent to) the metal material 120. An interface between the first titanium nitride material 115 and the metal material 120 is substantially continuous and extends in a vertical direction, and an interface between the metal material 120 and the second titanium nitride material 125 is substantially continuous and extends in a vertical direction. A width of the first titanium nitride material 115 may extend between opposing sidewalls of the dielectric material 110, a width of the metal material 120 may extend between opposing sidewalls of the dielectric material 110, and a width of the second titanium nitride material 125 may extend between opposing sidewalls of the dielectric material 110.

The wordline structure 100 also includes a conductive material 130 adjacent to (e.g., over) the second titanium nitride material 125, and a cap material 135 adjacent to (e.g., over) the conductive material 130. The conductive material 130 may, for example, be a polysilicon material. The cap material 135 may, for example, be a silicon nitride material. The second titanium nitride material 125, the conductive material 130, and the cap material 135 are present in an upper portion of the wordline structure 100. The dielectric material 110 (e.g. a gate dielectric material) may be a high-k dielectric material, such as a silicon oxide material or a silicon nitride material. The dielectric material 110 is present on sidewalls of the substrate 105 (e.g., on sidewalls of an opening defined by sidewalls of the substrate 105). Opposing sidewalls of the first titanium nitride material 115, metal material 120, second titanium nitride material 125, conductive material 130, and cap material 135 are in direct contact with the dielectric material 110. In contrast to conventional wordline structures, no barrier material or adhesion material, such as titanium nitride, is positioned between the dielectric material 110 and the materials of the wordline 140, such as the first titanium nitride material 115, metal material 120, and second titanium nitride material 125. No barrier material or adhesion material, such as titanium nitride, is positioned between the dielectric material 110 and the conductive material 130 and cap material 135.

As shown in FIG. 2, a wordline structure 100′ includes a substrate 105, a dielectric material 110, a first titanium nitride material 115′, a metal material 120′, and a second titanium nitride material 125. The wordline structure 100′ is substantially similar to the wordline structure 100 of FIG. 1 except that the first titanium nitride material 115′ may be heterogeneous in chemical composition and includes metal atoms of the metal material 120′. The wordline structure 100′ may include substantially the same materials at substantially the same material thicknesses as described above for the wordline structure 100. The first titanium nitride material 115′ varies in chemical composition throughout a thickness of the first titanium nitride material 115′. The first titanium nitride material 115′ may be the lower metal-containing material, the metal material 120′ may be the middle metal-containing material, and the second titanium nitride material 125 may be the upper metal-containing material. The first titanium nitride material 115′ is present in the lower portion of the wordline structure 100′, the metal material 120′ is adjacent to (e.g., over) the first titanium nitride material 115′, and the second titanium nitride material 125 is adjacent to (e.g., over) the metal material 120′. The metal material 120′ is present in the middle portion of the wordline structure 100′ and the second titanium nitride material 125 is present in the upper portion of the wordline structure 100′. The first titanium nitride material 115′, the metal material 120′, and the second titanium nitride material 125 form the wordline 140′. The metal material 120′ is in direct contact with (e.g., vertically adjacent to) the first titanium nitride material 115′ and the second titanium nitride material 125 is in direct contact with (e.g., vertically adjacent to) the metal material 120′. An interface between the first titanium nitride material 115′ and the metal material 120′ is substantially continuous and extends in a vertical direction, and an interface between the metal material 120′ and the second titanium nitride material 125 is substantially continuous and extends in a vertical direction. A width of the first titanium nitride material 115′ may extend between opposing sidewalls of the dielectric material 110, a width of the metal material 120′ may extend between opposing sidewalls of the dielectric material 110, and a width of the second titanium nitride material 125 may extend between opposing sidewalls of the dielectric material 110.

The upper portion of the wordline structure 100′ also includes a conductive material 130, such as a polysilicon material, adjacent to (e.g., over) the second titanium nitride material 125, and a cap material 135 adjacent to (e.g., over) the conductive material 130. The dielectric material 110 (e.g. a gate dielectric material) may be a high-k dielectric material, such as a silicon oxide material or a silicon nitride material. The dielectric material 110 is present on sidewalls of the substrate 105. Sidewalls of the first titanium nitride material 115′, metal material 120′, second titanium nitride material 125, conductive material 130, and cap material 135 are in direct contact with the dielectric material 110. In contrast to conventional wordline structures, no barrier material or adhesion material, such as titanium nitride, is positioned between the dielectric material 110 and the first titanium nitride material 115′, metal material 120′, and second titanium nitride material 125. No barrier material or adhesion material, such as titanium nitride, is positioned between the dielectric material 110 and the conductive material 130 and cap material 135.

The first titanium nitride material 115 may exhibit a single chemical composition throughout its thickness, as shown in FIG. 1. Each of the first and second titanium nitride materials 115, 125 may be substantially homogeneous in chemical composition throughout their respective thicknesses. The first and second titanium nitride materials 115, 125 may have the same chemical composition, or the first and second titanium nitride materials 115, 125 may differ in relative amounts of titanium atoms and nitrogen atoms. The first titanium nitride material 115′ may exhibit a heterogeneous chemical composition throughout its thickness and also includes the metal 120′ of the metal material 120, as shown in FIG. 2. The first and second titanium nitride materials 115′, 125 may, therefore, have different chemical compositions, with the first titanium nitride material 115′ including metal atoms in addition to the titanium atoms and nitrogen atoms.

The first titanium nitride material 115, 115′ may have a thickness of from about 20 nm to about 30 nm. The metal material 120 may have a thickness of from about 45 nm to about 55 nm, such as about 50 nm. The second titanium nitride material 125 may have a thickness of from about 0.5 nm to about 2.0 nm.

The metal material 120 may be tungsten, ruthenium, molybdenum, or a combination thereof. In some embodiments, the metal material 120 is tungsten. While specific embodiments herein describe the metal material 120 as tungsten, the metal material 120 may be ruthenium, molybdenum, or a combination of tungsten, ruthenium, and molybdenum by selecting a ruthenium precursor or a molybdenum precursor used to form the metal material 120.

Unlike conventional wordline structures, the wordline structure 100, 100′ according to embodiments of the disclosure includes the first titanium nitride material 115, 115′ in the lower portion of the wordline structure 100, 100′, the metal material 120, 120′ in the middle portion of the wordline structure 100, 100′, and the second titanium nitride material 125 in the upper portion of the wordline structure 100, 100′. The first titanium nitride material 115, 115′ may substantially reduce or eliminate bending of the wordline structures 100, 100′ in an electronic device containing the wordline structures 100, 100′. The metal material 120, 120′ may reduce wordline resistance of the wordline structures 100, 100′. The second titanium nitride material 125 may substantially reduce or eliminate interactions between the conductive material 130 and the metal material 120, 120′ of the wordline structures 100, 100′.

To form the wordline structure 100, an opening 145 is formed in the substrate 105 and is defined by sidewalls of the substrate 105, as shown in FIG. 3. The opening 145 may be formed by conventional techniques, such as by removing (e.g., etching) a portion of the substrate 105. The opening 145 may, for example, be configured as a wordline trench. Conventional etch conditions and etch chemistries are used to form the opening 145. The opening 145 may be from about 5 nm to about 20 nm wide and from about 150 nm to about 200 nm deep. The dielectric material 110 is formed in the opening 145, such as on the sidewalls of the substrate 105 that define the opening 145. The dielectric material 110 may be conformally formed adjacent to (e.g., on) the sidewalls of the substrate 105 and have a thickness of from about 10 Å to about 60 Å.

The first titanium nitride material 115 of the wordline structure 100 is formed in the opening 145 and adjacent to (e.g., on) the dielectric material 110. The first titanium nitride material 115 may be formed by conventional techniques to at least partially fill the opening 145. The first titanium nitride material 115 may, for example, be formed by CVD or ALD. The first titanium nitride material 115 may be formed to substantially fill the opening 145 and a portion removed (e.g., etched) so that the first titanium nitride material 115 partially fills the opening 145, as shown in FIG. 3. For instance, the first titanium nitride material 115 may substantially completely fill the opening 145 and then a portion may be removed so that the first titanium nitride material 115 partially fills the opening 145. The portion of the first titanium nitride material 115 may be removed, for example, by a dry etch process. By initially substantially filling the opening 145 with the first titanium nitride material 115, bending of the wordline structure 100 may be substantially reduced or eliminated. Alternatively, the first titanium nitride material 115 may be formed to partially but mostly fill the opening 145, as indicated by the dashed line, and then the portion may be removed so that the first titanium nitride material 115 partially fills the opening 145. For instance, about 100 Å of the first titanium nitride material 115 may be removed after forming the first titanium nitride material 115 to an initial depth. The removal of the first titanium nitride material 115 may be conducted by conventional techniques using conventional etch conditions and etch chemistries. After removing the portion, the first titanium nitride material 115 may occupy the lower portion of the opening 145. The first titanium nitride material 115 may have a thickness of from about 20 nm to about 30 nm. The first titanium nitride material 115 may directly contact the dielectric material 110, such as contacting opposing sidewalls of the first titanium nitride material 115.

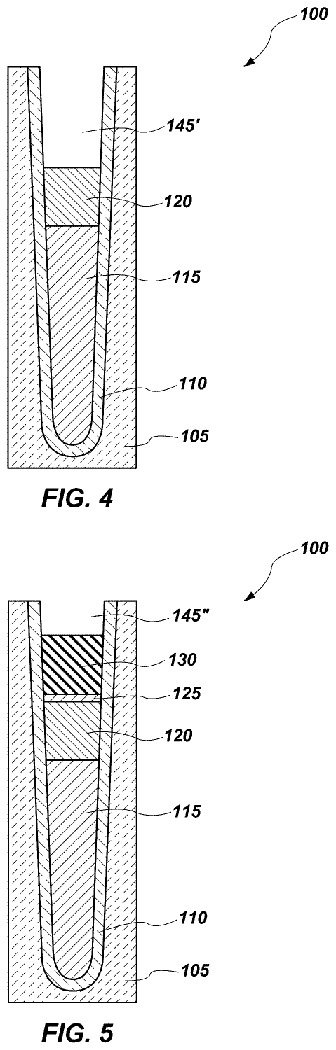

The metal material 120 is formed over the first titanium nitride material 115 as shown in FIG. 4. The metal material 120 may be formed by a so-called “bottom up” process in which the metal material 120 is selectively formed on the first titanium nitride material 115, such as on an upper surface of the first titanium nitride material 115. The formation of the metal material 120 initiates at the upper surface of the first titanium nitride material 115 and moves in a direction distal to the substrate 105 until a desired thickness of the metal material 120 is achieved. The metal material 120 may be formed at a thickness of about 50 nm. The metal material 120 selectively forms from the first titanium nitride material 115, rather than from the dielectric material 110, due to a difference in reactivity between a metal precursor of the metal material 120 and the first titanium nitride material 115 compared to the reactivity of the metal precursor and the dielectric material 110. Forming the metal material 120 reduces the volume of the opening 145 and forms opening 145′. Unlike conventional techniques, the formation of the metal material 120 according to embodiments of the disclosure does not initiate from the dielectric material 110 (e.g., from the sidewalls of the dielectric material). Since the metal material 120 forms from the first titanium nitride material 115, no barrier material or adhesion material is utilized to adhere the metal material 120 to the dielectric material 110. The metal material 120 may be formed in direct contact with the dielectric material 110, such as directly contacting the opposing sidewalls of the metal material 120, which directly contact the dielectric material 110. Therefore, and unlike with conventional wordline structures, no barrier material or adhesion material is present between the metal material 120 and the dielectric material 110.

The metal material 120 may be formed by a CVD process or by an ALD process that uses a metal precursor (e.g., a tungsten precursor) and a reducing agent. The metal precursor may be substantially free of fluorine atoms. Throughout the formation of the metal material 120, relative amounts of the metal precursor and the reducing agent may be adjusted to form the metal material 120 by the bottom up process. For instance, an initial portion of the metal material 120 may be formed on the upper surface of the first titanium nitride material 115 by subjecting the first titanium nitride material 115 to gases that include a relatively low amount of the metal precursor and a relatively high amount of the reducing agent. By way of example only, the metal precursor may initially account for from about 5% to about 20% of a volume of the gases introduced to a chamber (e.g., a CVD chamber, an ALD chamber) in which a partially-formed wordline structure 100 is placed and the reducing agent may initially account for from about 80% to about 95% of the volume of the gases introduced to the chamber. After forming the initial portion, the metal material 120 may be formed to the desired thickness by increasing the amount of the metal precursor relative to the amount of the reducing agent. By way of example only, the metal precursor may account for from about 40% to about 80% of the volume of the gases and the reducing agent may initially account for from about 20% to about 60% of the volume of the gases to form the metal material 120 to the desired thickness.

If the metal material 120 is, for example, tungsten, a tungsten precursor may be a chlorine-based tungsten precursor, such as a WClₓ gas where x is an integer between 2 and 6. The reducing agent may be hydrogen, such as H₂ gas. The WClₓ and H₂ gases may be sequentially introduced into the chamber in which a partially-formed wordline structure 100 is placed, such as the wordline structure 100 at the stage illustrated in FIG. 3. CVD process and ALD process, as well as CVD chambers and ALD chambers, are known in the art and are not described in detail herein. The WClₓ gas may be used as the tungsten precursor to prevent or substantially reduce damage to the first titanium nitride material 115, which damage is observed when conventional fluorine-based tungsten precursors are used. The WClₓ gas may include, but is not limited to, WCl₂, WCl₄, WCl₅, WCl₆, or a combination thereof. Throughout the formation of the tungsten material 120, relative amounts of the WClₓ gas and the H₂ gas may be adjusted. An initial portion of the tungsten material 120 may be formed on the upper surface of the first titanium nitride material 115 by exposing the partially-formed wordline structure 100 to the WClₓ gas and the H₂ gas, with a greater amount of H₂ gas present relative to the amount of WClₓ gas. To achieve the desired relative amount of the WClₓ and H₂ gases, the flow rate of the H₂ gas into the chamber may be greater than the flow rate of the WClₓ gas. By introducing the WClₓ gas into the chamber at a lower flow rate than the H₂ gas, the initial portion of the tungsten material 120 is formed on the upper surface of the first titanium nitride material 115 without damaging (e.g., etching) the first titanium nitride material 115 and without substantially incorporating tungsten into the first titanium nitride material 115. By way of example only, the flow rate of the H₂ gas may initially be from about 100 sccm to about 3000 sccm, and the flow rate of the WClₓ gas may initially be from about 10 mg/m to about 300 mg/m. The WClₓ gas may react with the hydrogen gas to form the tungsten material 120 on the first titanium nitride material 115. Without being bound by any theory, it is believed that the tungsten material 120 selectively forms on the first titanium nitride material 115 due to a difference in reactivity between the tungsten precursor and the first titanium nitride material 115 compared to the tungsten precursor and the dielectric material 110. Forming the tungsten material 120 using the WClₓ gas eliminates the necessity for forming a tungsten nucleation layer on the dielectric material 110 or a barrier/adhesion material on the dielectric material 110.

After forming the initial portion, the tungsten material 120 may be formed to the desired thickness by increasing the amount of the tungsten precursor relative to the amount of the H₂ gas. By way of example only, the tungsten precursor may account for from about 40% to about 80% of the volume of the gases and the H₂ gas may initially account for from about 20% to about 60% of the volume of the gases to form the tungsten material 120 to the desired thickness.

The second titanium nitride material 125 may be formed over the metal material 120, as shown in FIG. 5. The second titanium nitride material 125 may be formed by, for example, PVD. The second titanium nitride material 125 may be formed at a thickness of from about 0.5 nm to about 2.0 nm. The second titanium nitride material 125 may be substantially the same chemical composition as the first titanium nitride material 115. The second titanium nitride material 125 may partially fill the opening 145′. The wordline 140 according to embodiments of the disclosure includes the first titanium nitride material 115, the metal material 120, and the second titanium nitride material 125 positioned vertically over one another. The conductive material 130 may be formed over the second titanium nitride material 125 and in the opening 145′. A portion of the conductive material 130 may be removed, recessing the conductive material 130 and forming opening 145″ as shown in FIG. 5. The portion of the conductive material 130 may be removed, for example, by a dry etch process. The conductive material 130 in FIG. 5 may have a thickness of from about 50 Å to about 300 Å. The cap material 135 may be formed over the conductive material 130 and in the opening 145″, producing the wordline structure 100 of FIG. 1. The cap material 135 may have a thickness of from about 400 Å to about 800 Å. The conductive material 130 and the cap material 135 may be formed by conventional techniques.

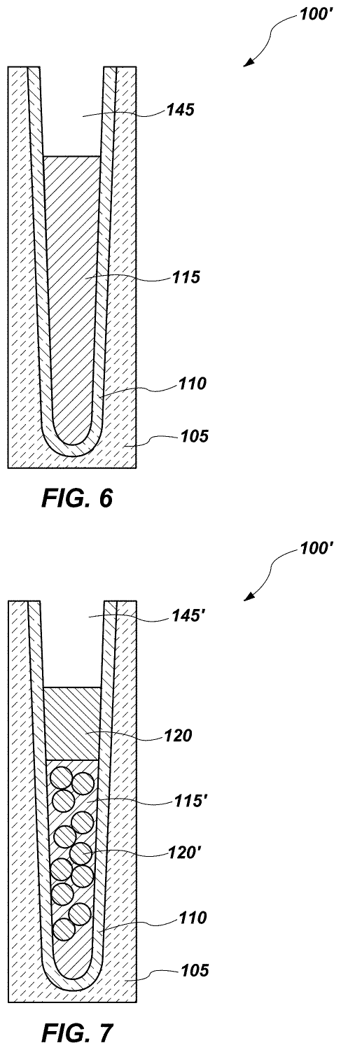

To form the wordline structure 100′, substantially similar process acts to those described above for the wordline structure 100 may be conducted, except that the first titanium nitride material 115′ is heterogeneous in chemical composition. As shown in FIG. 6, the wordline structure 100′ includes the substrate 105, the dielectric material 110, the opening 145′, and the first titanium nitride material 115. The opening 145′, the dielectric material 110, and the first titanium nitride material 115 may be formed as described above. The first titanium nitride material 115 is formed to the initial depth as described above for FIG. 3 and then recessed.

The metal material 120′ is formed in the opening 145′ and on the first titanium nitride material 115 by CVD or by ALD using the metal precursor (e.g., a tungsten precursor) and the reducing agent. The metal precursor may be substantially free of fluorine atoms. Relative amounts of the metal precursor and the reducing agent may be adjusted to form the metal material 120′ by the bottom up process. The metal material 120′ may be formed on the first titanium nitride material 115 and in the first titanium nitride material 115 by initially subjecting the first titanium nitride material 115 to the metal precursor with substantially no reducing agent present, which etches and incorporates metal 120′ into the first titanium nitride material 115′ as shown in FIG. 7. By way of example only, the metal precursor may initially account for from about 90% to about 99% of a volume of the gases introduced to the chamber and the reducing agent may initially account for from about 10% to about 20% of the volume of the gases introduced to the chamber. By etching the first titanium nitride material 115 in the presence of the metal precursor, with substantially no reducing agent present, the metal 120′ is incorporated into the first titanium nitride material 115′. The metal 120′ is heterogeneously dispersed throughout the first titanium nitride material 115′, which is illustrated for convenience in FIG. 7 as circular-shaped regions. However, the metal 120′ may be otherwise heterogeneously dispersed in the first titanium nitride material 115′, such as including the metal 120′ in regions of the first titanium nitride material 115′. The first titanium nitride material 115′ thus, includes the metal and titanium nitride. The amount of reducing agent to which the first titanium nitride material 115′ is exposed may subsequently be increased relative to the amount of the metal precursor, forming the metal material 120′ on the first titanium nitride material 115′ to the desired thickness. By way of example only, the metal precursor may account for from about 40% to about 80% of a volume of the gases introduced to the chamber and the reducing agent may account for from about 20% to about 60% of the volume of the gases introduced to the chamber. By way of example only, the flow rate of the reducing agent may be about 0 sccm, and the flow rate of the metal precursor may be from about 10 mg/m to about 300 mg/m.

If the metal material 120′ is, for example, tungsten, the tungsten precursor may be the chlorine-based tungsten precursor, such as the WClₓ gas where x is an integer between 2 and 6. The reducing agent may be hydrogen, such as H₂ gas. The WClₓ and H₂ gases may be sequentially introduced into the chamber including a partially-formed wordline structure 100′, such as the wordline structure 100′ at the stage illustrated in FIG. 6. The WClₓ gas may include, but is not limited to, WCl₂, WCl₄, WCl₅, WCl₆, or a combination thereof. Throughout the formation of the tungsten material 120, relative amounts of the WClₓ gas and the H₂ gas may be adjusted. Initially, the partially-formed wordline structure 100′ is exposed to the WClₓ gas, with substantially no H₂ gas present, etching the first titanium nitride material 115 and incorporating tungsten 120′ into the first titanium nitride material 115′, as shown in FIG. 7. The amount of H₂ gas may then be increased so that the metal material 120′ is formed to the desired thickness. To achieve the desired relative amounts of the WClₓ and H₂ gases, the flow rates of the WClₓ gas and the H₂ gas into the chamber may be adjusted. The WClₓ gas may account for from about 90% to about 99% of a volume of the gases in the chamber and the H₂ gas may account for from about 10% to about 20% of the volume of the gases in the chamber. By way of example only, the flow rate of the WClₓ gas may be from about 10 mg/m to about 300 mg/m and the flow rate of the H₂ gas may be from about 100 sccm to about 3000 sccm. The WClₓ gas may react with the H₂ gas to form the tungsten material 120 on the first titanium nitride material 115′.

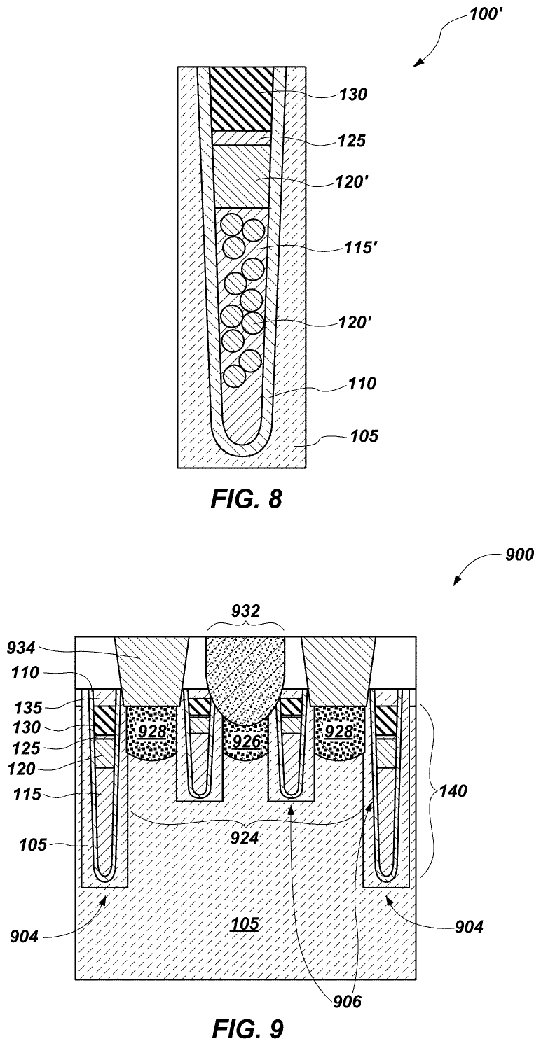

The second titanium nitride material 125 may be formed over the metal material 120′, as shown in FIG. 8. The second titanium nitride material 125 may be formed by, for example, PVD. The second titanium nitride material 125 may be formed at a thickness of from about 0.5 nm to about 2.0 nm. The second titanium nitride material 125 may be substantially the same chemical composition as the as-formed (e.g., before the incorporation of metal) first titanium nitride material 115. The second titanium nitride material 125 may partially fill the opening 145′. The conductive material 130 may be formed over the second titanium nitride material 125, as shown in FIG. 8, a portion of the conductive material 130 removed to form opening 145″, and the cap material 135 formed over the conductive material 130 and in the opening 145″, producing the wordline structure 100′ as shown in FIG. 2. The conductive material 130 and the cap material 135 may be formed by conventional techniques. The wordline 140′ according to embodiments of the disclosure includes the first titanium nitride material 115′, the metal material 120′, and the second titanium nitride material 125.

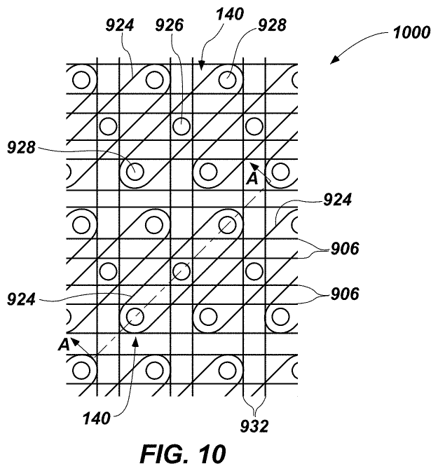

Additional process acts may be conducted to form an apparatus 900 (e.g., an electronic device, a semiconductor device, a memory device) that includes the wordlines 140, 140′ according to embodiments of the disclosure and additional components, as shown in FIG. 9. While FIG. 9 illustrates the apparatus 900 including the wordlines 140, the wordlines 140′ may be present in the apparatus 900 in place of the wordlines 140. The subsequent process acts are conducted by conventional techniques, which are not described in detail herein. The electronic device 900 includes one or more wordlines 140, 140′ (e.g., access lines, gates), at least one bit line 932, and at least one memory cell (not shown). Each memory cell is coupled to an associated wordline 140, 140′ and an associated bit line 932, and may include one access device (e.g., a transistor) and one storage device (e.g., a capacitor). The bit lines 932 may be formed of at least one conductive material. While the bit line 932 is illustrated as a single material in FIG. 9, the bit line 932 may be formed of multiple electrically conductive materials. By way of example only, the bit line 932 may include a metal material over a polysilicon material. The wordline 140, 140′ may be a so-called “buried wordline” since the wordline 140, 140′ is located within the substrate 105 and is isolated from the source 926 and drains 928 by the dielectric material 110. The memory cells are electrically accessible through the wordlines 140, 140′ and bit lines 932 arranged along rows and columns of an array 1000 (see FIG. 10). The electronic device 900 also includes active areas 924, which may be aligned at an angle (e.g., at about a forty-five degree angle) relative to the alignment of the wordlines 140, 140′ (within the wordline trenches 906) and the bit lines 932 (within isolation trenches 904). Each wordline 140, 140′ is isolated from a source 926 and drains 928 of the array by the dielectric material 110. The electronic device 900 may, for example, be a dynamic random access memory (DRAM) device.

As shown in FIG. 10, the electronic device 900 may include the array 1000 (e.g., memory array) of memory cells that include the wordlines 140, 140′ according to embodiments of the disclosure, where the view of FIG. 9 is taken along section line A-A of FIG. 10. The memory cells are positioned between the access lines (e.g., wordlines 140, 140′) and digit lines (e.g., bit lines 932). Additional processing acts may be conducted by conventional techniques to form the electronic device 900 that includes the array 1000 of memory cells. The wordlines 140, 140′ may be oriented perpendicular or substantially perpendicular to the bit lines 932. The bit line 932 may extend vertically to the source 926, providing electrical communication with the source 926. A digit line contact (not shown) including conductive material 934 extends vertically to the bit line 932 to enable electrical communication with more distal components of the electronic device 900 that includes the wordlines 140, 140′. Contacts formed from the conductive material 934 are in electrical communication with the drains 928.

The conductive material of the bit lines 932 and the conductive material 934 may include an electrically conductive material including, but not limited to, tungsten, aluminum, copper, titanium, tantalum, platinum, alloys thereof, heavily doped semiconductor material, polysilicon, a conductive silicide, a conductive nitride, a conductive carbon, a conductive carbide, or combinations thereof.

Accordingly, an apparatus that comprises a wordline in a material is disclosed. The wordline comprises a first metal portion, a second metal portion vertically adjacent to the first metal portion, and a third metal portion vertically adjacent to the second metal portion. A dielectric material is between the wordline and the material.

Accordingly, an apparatus that comprises a memory array comprising wordlines, bit lines, and memory cells is disclosed. Each memory cell is coupled to an associated one of the wordlines and an associated one of the bit lines. Each of the wordlines is located in a material and comprises a first titanium nitride portion, a metal portion, and a second titanium nitride portion vertically stacked on one another. A dielectric material in direct contact with the wordlines and with the material.

Accordingly, a method of forming an apparatus is disclosed. The method comprises forming a first metal portion in an opening in a material and adjacent to a dielectric material in the opening, forming a second metal portion vertically adjacent to the first metal portion, forming a third metal portion vertically adjacent to the second metal portion, and forming polysilicon adjacent to the third metal portion. The first metal portion, the second metal portion, and the third metal portion comprise a wordline.

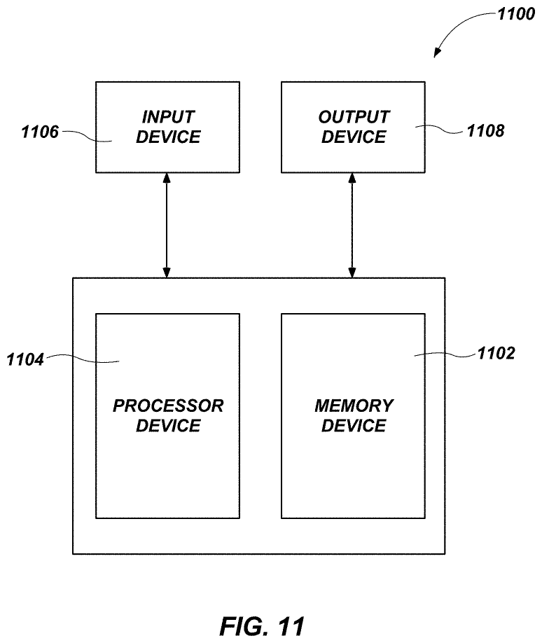

An electronic system 1100 is also disclosed, as shown in FIG. 1, and includes electronic devices 900 and wordlines 140, 140′ according to embodiments of the disclosure. FIG. 11 is a simplified block diagram of the electronic system 1100 implemented according to one or more embodiments described herein. The electronic system 100 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 1100 includes at least one electronic device 900 (e.g., at least one memory device), which includes memory cells including one or more wordline structures 100, 100′ as previously described. The electronic system 1100 may further include at least one processor device 1104 (often referred to as a “processor”). The processor device 1104 may, optionally, include one or more wordlines 140, 140′ as previously described. The electronic system 1100 may further include one or more input devices 1106 for inputting information into the electronic system 1100 by a user, such as, for example, a mouse or other pointing device, a keyboard, a touchpad, a button, or a control panel. The electronic system 1100 may further include one or more output devices 1108 for outputting information (e.g., visual or audio output) to a user such as, for example, a monitor, a display, a printer, an audio output jack, a speaker, etc. In some embodiments, the input device 1106 and the output device 1108 may comprise a single touchscreen device that can be used both to input information to the electronic system 1100 and to output visual information to a user. The one or more input devices 1106 and output devices 1108 may communicate electrically with at least one of the memory device 1102 and the processor device 1104.

Accordingly, an electronic system comprising a processor operably coupled to an input device and an output device and an apparatus operably coupled to the processor is disclosed. The apparatus comprises wordlines, bit lines, and memory cells, each memory cell coupled to an associated one of the wordlines and an associated one of the bit lines. Each of the wordlines comprises a first titanium nitride material, a tungsten material over the first titanium nitride material, and a second titanium nitride material over the tungsten material.

The following example serves to explain embodiments of the disclosure in more detail. These examples are not to be construed as being exhaustive or exclusive as to the scope of this disclosure.

### EXAMPLE

### Example 1

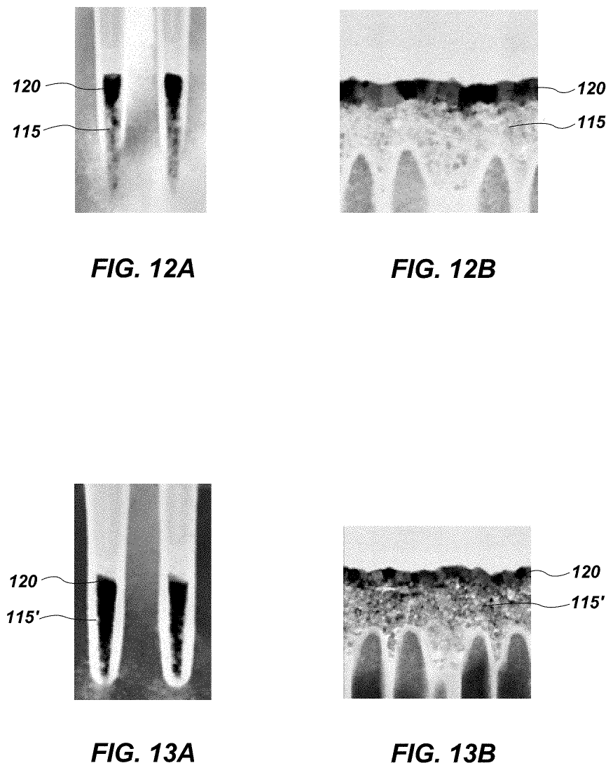

Wordline sample A including a first titanium nitride material, tungsten over the first titanium nitride material, a second titanium nitride material over the tungsten, and polysilicon over the second titanium nitride material was prepared as described above for FIGS. 1 and 3-5. A silicon nitride cap was formed over the polysilicon. Two perspectives of wordline sample A including the first titanium nitride material 115 and the tungsten 120 are shown in scanning electron micrograph (SEM) images in FIGS. 12A and 12B.

Wordline sample B including a heterogeneous titanium nitride/tungsten material, tungsten over the heterogeneous titanium nitride/tungsten material, a titanium nitride material over the tungsten, and polysilicon over the second titanium nitride material was prepared as described above for FIGS. 2 and 6-8. A silicon nitride cap was formed over the polysilicon. Two perspectives of wordline sample B including the heterogeneous titanium nitride 115′ and the tungsten 120 are shown in the SEM images of FIGS. 13A and 13B.

A first control sample was prepared in which the wordline included titanium nitride and polysilicon over the titanium nitride. A silicon nitride cap was formed over the polysilicon. A second control sample was prepared in which the wordline included titanium nitride with nucleation tungsten on sidewalls of the titanium nitride and bulk tungsten between the nucleation tungsten, and polysilicon over the titanium nitride. A silicon nitride cap was formed over the polysilicon.

Line bending of the samples was determined by conventional techniques. No line bending was observed in the wordline samples A and B according to embodiments of the disclosure or in the first control sample. However, the second control sample exhibited significant line bending. Wordline samples A and B according to embodiments of the disclosure, therefore, exhibited a comparable degree of line bending to the first control sample and substantially less line bending relative to the second control sample.

Wordline resistance of the samples were determined by conventional techniques The wordline samples A and B according to embodiments of the disclosure exhibited decreased wordline resistance compared to that of the first and second control samples. Wordline sample A had a resistance of 71.6 ohm/cell, wordline sample B had a resistance of 73.7 ohm/cell, the first control sample had a resistance of 96.7 ohm/cell, and the second control sample had a resistance of 155 ohm/cell. The wordline samples A and B according to embodiments of the disclosure, therefore, exhibited a 26% lower wordline resistance than the first control sample and a substantially lower wordline resistance than the second control sample.

Therefore, the wordline samples A and B according to embodiments of the disclosure achieved both lower wordline resistance and substantially no line bending. The lower wordline resistance and reduced line bending were achieved without degradation in transistor performance.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. An apparatus comprising:
a wordline in a material, the wordline comprising a first metal portion, a second metal portion vertically adjacent to the first metal portion, and a third metal portion vertically adjacent to the second metal portion; and
a dielectric material between the wordline and the material.

2. The apparatus of claim 1, wherein each of the first metal portion and the third metal portion comprises titanium nitride and the second metal portion comprises tungsten.

3. The apparatus of claim 1, wherein the first metal portion comprises titanium nitride and tungsten, the second metal portion comprises tungsten, and the third metal portion comprises titanium nitride.

4. The apparatus of claim 1, wherein the second metal portion directly contacts the dielectric material.

5. The apparatus of claim 1, wherein the first metal portion comprises a substantially homogeneous chemical composition.

6. The apparatus of claim 1, wherein the first metal portion comprises a heterogeneous chemical composition.

7. The apparatus of claim 1, wherein the second metal portion directly contacts the first metal portion and the third metal portion directly contacts the second metal portion.

8. An apparatus comprising:
a memory array comprising wordlines, bit lines, and memory cells, each memory cell coupled to an associated one of the wordlines and an associated one of the bit lines, each of the wordlines located in a material and comprising:
a first titanium nitride portion, a metal portion, and a second titanium nitride portion vertically stacked on one another; and
a dielectric material in direct contact with the wordlines and with the material.

9. The apparatus of claim 8, wherein the metal portion comprises tungsten, ruthenium, molybdenum, or a combination thereof.

10. The apparatus of claim 8, wherein the metal portion directly contacts the first titanium nitride portion and the second titanium nitride portion directly contacts the metal portion.

11. The apparatus of claim 8, wherein no titanium nitride material is between the wordlines and the dielectric material.

12. The apparatus of claim 8, wherein a metal of the metal portion exhibits a lower resistivity than a resistivity of the first titanium nitride portion and the second titanium nitride portion.

13. A method of forming an apparatus, comprising:
forming a first metal portion in an opening in a material and adjacent to a dielectric material in the opening;
forming a second metal portion vertically adjacent to the first metal portion;
forming a third metal portion vertically adjacent to the second metal portion, the first metal portion, the second metal portion, and the third metal portion comprising a wordline; and
forming polysilicon adjacent to the third metal portion.

14. The method of claim 13, wherein forming a second metal portion vertically adjacent to the first metal portion comprises:
sequentially introducing a metal chloride precursor and hydrogen gas into the opening; and
reacting the metal chloride precursor with the hydrogen gas to form the second metal portion vertically adjacent to the first metal portion.

15. The method of claim 14, wherein sequentially introducing a metal chloride precursor and hydrogen gas into the opening comprises sequentially introducing a tungsten chloride precursor comprising WCl₂, WCl₄, WCl₅, WCl₆, or a combination thereof and hydrogen gas into the opening.

16. The method of claim 15, wherein sequentially introducing a tungsten chloride precursor and hydrogen gas into the opening comprises:
sequentially introducing a relatively low amount of the tungsten chloride precursor and a relatively high amount of the hydrogen gas into the opening;
reacting the tungsten chloride precursor and the hydrogen gas to form an initial tungsten portion vertically adjacent to the first metal portion; and
increasing the amount of the tungsten chloride precursor relative to the amount of the hydrogen gas to form a tungsten portion vertically adjacent to the first metal portion.

17. The method of claim 15, wherein sequentially introducing a metal chloride precursor and hydrogen gas into the opening comprises sequentially introducing from about 10 mg/m to about 300 mg/m of the tungsten chloride precursor and from about 100 sccm to about 3000 sccm of the hydrogen gas into the opening.

18. The method of claim 16, wherein forming a tungsten portion vertically adjacent to the first metal portion comprises forming the tungsten portion vertically adjacent to the first metal portion comprising a homogeneous composition.

19. The method of claim 15, wherein sequentially introducing a tungsten chloride precursor and hydrogen gas into the opening comprises:
sequentially introducing a relatively high amount of the tungsten chloride precursor and a relatively low amount of the hydrogen gas;
reacting the tungsten chloride precursor and the hydrogen gas to incorporate tungsten into the first metal portion; and
increasing the amount of the hydrogen gas relative to the amount of the tungsten chloride precursor to form a tungsten portion vertically adjacent to the first metal portion.

20. The method of claim 19, wherein reacting the tungsten chloride precursor and the hydrogen gas to incorporate tungsten into the first metal portion comprises heterogeneously dispersing the tungsten in the first metal portion.

21. The method of claim 19, wherein forming a tungsten portion vertically adjacent to the first metal portion comprises forming the tungsten portion vertically adjacent to the first metal portion comprising a heterogeneous composition.

22. The method of claim 21, wherein forming the tungsten portion vertically adjacent to the first metal portion comprising a heterogeneous composition comprises forming the tungsten portion vertically adjacent to the heterogeneous composition comprising titanium nitride and tungsten.

23. An electronic system, comprising:
a processor operably coupled to an input device and an output device; and
an apparatus operably coupled to the processor, the apparatus comprising:
wordlines, bit lines, and memory cells, each memory cell coupled to an associated one of the wordlines and an associated one of the bit lines, each of the wordline comprising:
a first titanium nitride material, a tungsten material over the first titanium nitride material, and a second titanium nitride material over the tungsten material.

24. The electronic system of claim 23, wherein the first titanium nitride material comprises a homogeneous composition.

25. The electronic system of claim 23, wherein the first titanium nitride material comprises a heterogeneous composition.
